(19) United States
(12) Patent Application Publication
(10) Pub. No.: US 2025/0349573 A1
(43) Pub. Date: Nov. 13, 2025

(54) SUBSTRATE PROCESSING APPARATUS

(71) Applicant: Tokyo Electron Limited, Tokyo (JP)

(72) Inventors: Norihiko AMIKURA, Miyagi (JP); Kazuya NAGASEKI, Miyagi (JP)

(73) Assignee: Tokyo Electron Limited, Tokyo (JP)

(21) Appl. No.: 19/287,826

(22) Filed: Aug. 1, 2025

Related U.S. Application Data
(63) Continuation of application No. PCT/JP2024/002792, filed on Jan. 30, 2024.

(30) Foreign Application Priority Data
Feb. 9, 2023 (JP) 2023-018670

(51) Int. Cl. H01L 21/67; H01L 21/677

(52) U.S. Cl. CPC H01L 21/6719; H01L 21/67196; H01L 21/67201; H01L 21/67709

(57) ABSTRACT

Provided is a substrate processing apparatus for processing a substrate, the substrate processing apparatus having: composite modules in each of which one transfer chamber having a transfer space for the substrate and a processing chamber having a processing space for the substrate are integrated, in which the composite modules are connected by connecting the transfer chambers adjacent to each other. The transfer spaces of the transfer chambers connected to each other communicate with each other. The transfer space is maintained in a vacuum atmosphere.

### CROSS-REFERENCE TO RELATED APPLICATIONS

This application is a bypass continuation application of international application No. PCT/JP2024/002792, having an international filing date of Jan. 30, 2024, and designating the United States, the international application being based upon and claiming the benefit of priority from Japanese Patent Application No. 2023-018670, filed on Feb. 9, 2023, the entire contents of each are incorporated herein by reference.

### TECHNICAL FIELD

The present disclosure relates to a substrate processing apparatus.

### BACKGROUND

PTL 1 discloses a substrate processing apparatus in which processing modules are connected to a vacuum transfer module. An example of the substrate processing apparatus has a configuration in which a first vacuum transfer module and a second vacuum transfer module are coupled, and six processing modules are connected to each vacuum transfer module.

### CITATION LIST

### Patent Documents

PTL 1: JP2022-104056A

### SUMMARY

The technique according to the present disclosure improves the production efficiency of a substrate processing apparatus.

An aspect of the present disclosure is a substrate processing apparatus for processing a substrate, the substrate processing apparatus having: composite modules in each of which one transfer chamber having a transfer space for the substrate and a processing chamber having a processing space for the substrate are integrated, in which the composite modules are connected by connecting the transfer chambers adjacent to each other.

According to the present disclosure, it is possible to improve the production efficiency of the substrate processing apparatus.

### BRIEF DESCRIPTION OF DRAWINGS

FIG. 1 is a perspective view illustrating a schematic configuration of a wafer processing apparatus according to the present embodiment.

FIG. 2 is a plan view illustrating a schematic configuration of the wafer processing apparatus according to the present embodiment.

FIG. 3 is a view schematically illustrating a schematic configuration of a composite module.

FIG. 4 is a view schematically illustrating a schematic configuration of both end surfaces of a transfer chamber.

FIG. 5 is a plan view illustrating a schematic configuration of a transfer unit.

FIG. 6 is a side view illustrating a schematic configuration of the composite module.

FIG. 7 is a view illustrating a state of producing the wafer processing apparatus.

FIG. 8 is a plan view illustrating a schematic configuration of a wafer processing apparatus according to another embodiment.

FIG. 9 is a plan view illustrating a schematic configuration of a wafer processing apparatus according to another embodiment.

FIG. 10 is a plan view illustrating a schematic configuration of a wafer processing apparatus according to another embodiment.

FIG. 11 is a plan view illustrating a schematic configuration of a wafer processing apparatus according to another embodiment.

FIG. 12 is a plan view illustrating a schematic configuration of a wafer processing apparatus according to another embodiment.

FIG. 13A is a plan view illustrating a schematic configuration of a wafer processing apparatus in the related art.

FIG. 13B is a plan view illustrating a schematic configuration of the wafer processing apparatus in the related art.

FIG. 13C is a plan view illustrating a schematic configuration of the wafer processing apparatus in the related art.

FIG. 13D is a plan view illustrating a schematic configuration of the wafer processing apparatus in the related art.

FIG. 13E is a plan view illustrating a schematic configuration of the wafer processing apparatus in the related art.

FIG. 14 is a view illustrating a state of producing the wafer processing apparatus in the relater art.

FIG. 15 is a plan view illustrating a schematic configuration of the wafer processing apparatus in the related art.

### DETAILED DESCRIPTION

In a process of producing a semiconductor device, various processing steps of bringing an inside of a processing module in which a semiconductor wafer (a substrate, hereinafter, referred to as simply a “wafer”) is accommodated into a vacuum (decompressed) state and processing the wafer are performed. These processing steps are performed in a wafer processing apparatus (a substrate processing apparatus) including the processing modules.

The wafer processing apparatus includes, for example, an atmospheric unit including an atmospheric module that processes and transfers a wafer under an atmospheric atmosphere, and a vacuum unit (a decompression unit) including a vacuum module (a decompression module) that processes and transfers a wafer under a vacuum atmosphere (a vacuum environment). The atmospheric unit and the vacuum unit are integrally connected via a load-lock module capable of switching an inside thereof between the atmospheric atmosphere and the vacuum atmosphere.

When designing the wafer processing apparatus, it is known to connect the processing modules to one transfer module in the vacuum unit. For example, as disclosed in PTL 1, two transfer modules are connected as a transfer system.

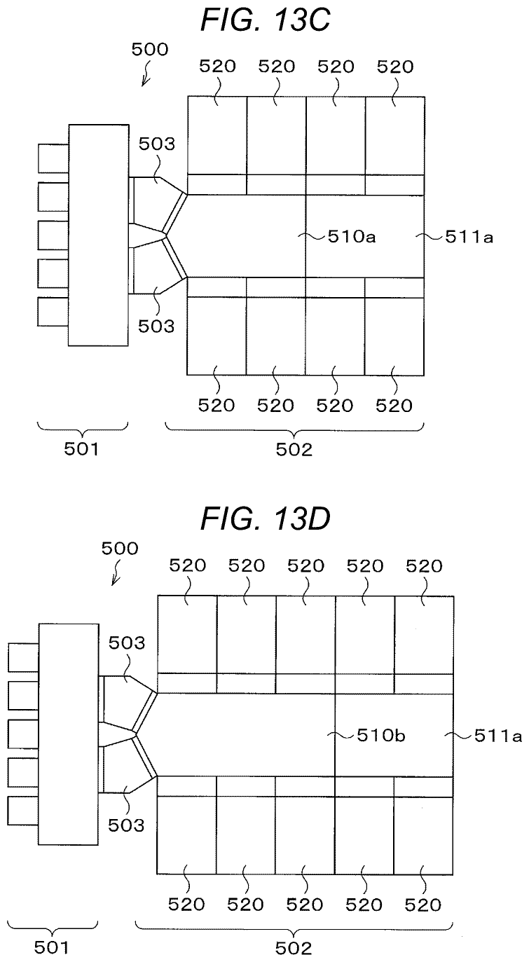

Examples of a wafer processing apparatus 500 in the related art will be described in FIGS. 13A to 13E. The wafer processing apparatus 500 has a configuration in which an atmospheric unit 501 and a vacuum unit 502 are connected via two load-lock modules 503. The vacuum unit 502 includes a first transfer module 510. In the present example, two types of first transfer modules 510a and 510b are prepared as the first transfer module 510. Four processing modules 520 are connected to the first transfer module 510a. Six processing modules 520 are connected to the first transfer module 510b.

The vacuum unit 502 may include a second transfer module 511 connected to the first transfer module 510 on a side opposite to the load-lock module 503 with the first transfer module 510 sandwiched therebetween. In the present example, two types of second transfer modules 511a and 511b are prepared as the second transfer module 511. Four processing modules 520 are connected to the second transfer module 511a. Six processing modules 520 are connected to the second transfer module 511b.

The wafer processing apparatus 500 has a configuration in which the first transfer modules 510a and 510b and the second transfer modules 511a and 511b are freely combined. In other words, the first transfer modules 510a and 510b and the second transfer modules 511a and 511b are combined according to the required number of the processing modules 520.

FIG. 13A illustrates a case in which four processing modules 520 are required, and the wafer processing apparatus 500 has a configuration in which four processing modules 520 are connected to the first transfer module 510a.

FIG. 13B illustrates a case in which six processing modules 520 are required, and the wafer processing apparatus 500 has a configuration in which six processing modules 520 are connected to the first transfer module 510b.

FIG. 13C illustrates a case in which eight processing modules 520 are required, and the wafer processing apparatus 500 has a configuration in which four processing modules 520 are connected to the first transfer module 510a and four processing modules 520 are connected to the second transfer module 511a.

FIG. 13D illustrates a case in which ten processing modules 520 are required, and the wafer processing apparatus 500 has a configuration in which six processing modules 520 are connected to the first transfer module 510b and four processing modules 520 are connected to the second transfer module 511a.

FIG. 13E illustrates a case in which twelve processing modules 520 are required, and the wafer processing apparatus 500 has a configuration in which six processing modules 520 are connected to the first transfer module 510b and six processing modules 520 are connected to the second transfer module 511b.

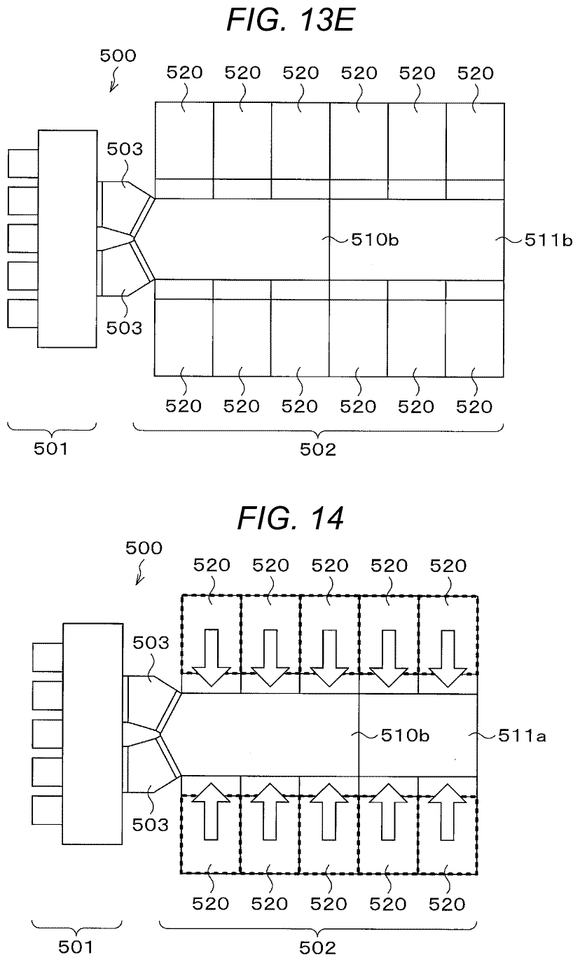

A method of producing the wafer processing apparatus 500 in the related art will be described by taking the wafer processing apparatus 500 illustrated in FIG. 13D as an example. As illustrated in FIG. 14, first, a transfer chamber of the first transfer module 510b and a transfer chamber of the second transfer module 511a are connected to each other to connect the first transfer module 510b and the second transfer module 511a. In this way, a transfer system is prepared. At this time, the atmospheric unit 501 and the load-lock module 503 are connected to the first transfer module 510b.

Next, processing chambers of the six processing modules 520 are connected (docked) to the transfer chamber of the first transfer module 510b, and processing chambers of the four processing modules 520 are connected (docked) to the transfer chamber of the second transfer module 511a. In this way, the first transfer module 510b and the second transfer module 511a, which serve as the transfer system, and the ten processing modules 520 are independently prepared and connected, thereby producing the wafer processing apparatus 500.

As described above, the wafer processing apparatus 500 in the related art has a configuration in which the transfer modules 510 and 511 and the processing modules 520 are independent from one another. Therefore, the following problems have been encountered.

### (Problem 1)

Types (variations) of transfer modules 510 and 511 need to be prepared according to the required number of the processing modules 520. In the present example, four types of transfer modules 510a, 510b, 511a, and 511b are prepared.

### (Problem 2)

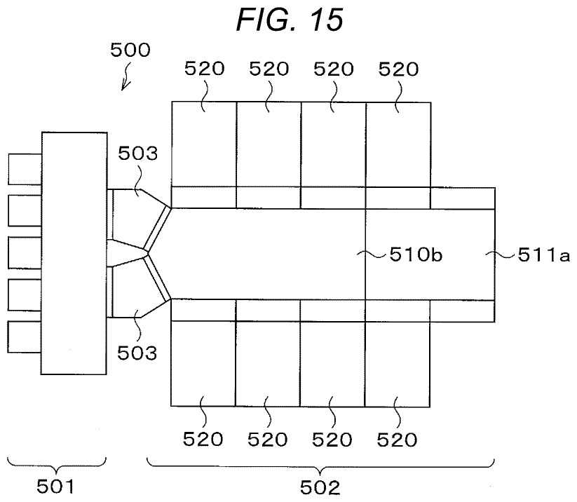

Since it is required to prepare types of transfer modules 510 and 511 according to the required number of processing modules 520, wasteful spaces or layouts may occur. For example, when the existing wafer processing apparatus 500 has a configuration in which six processing modules 520 are connected to the first transfer module 510b as illustrated in FIG. 15, two processing modules 520 are additionally provided. In this case, since it is required to connect the second transfer module 511a to the first transfer module 510b, spaces for connecting two processing modules 520 in the second transfer module 511a are wasted.

### (Problem 3)

Since it is required to separately connect the processing modules 520 to the transfer modules 510 and 511, this requires labor. For example, as illustrated in FIG. 14, it is required to connect ten processing modules 520 to the transfer modules 510b and 511a, which requires labor.

### (Problem 4)

Since the processing modules 520 are provided independently, each processing module 520 needs to have independent apparatuses required for wafer processing. The apparatuses include an apparatus required for performing desired processing on a wafer in the processing module 520, and include, for example, an utility source, a gas box, a gas line, a vacuum pump, a vacuum line, a cooling water supply mechanism, a frame, and a caster device.

Therefore, the technique according to the present disclosure improves the production efficiency of the substrate processing apparatus. Hereinafter, a wafer processing apparatus as a substrate processing apparatus according to the present embodiment will be described with reference to the drawings. The same reference numerals will be given to elements having substantially the same functional configurations throughout the specification and the drawings, and redundant description thereof will be omitted.

### <Wafer Processing Apparatus>

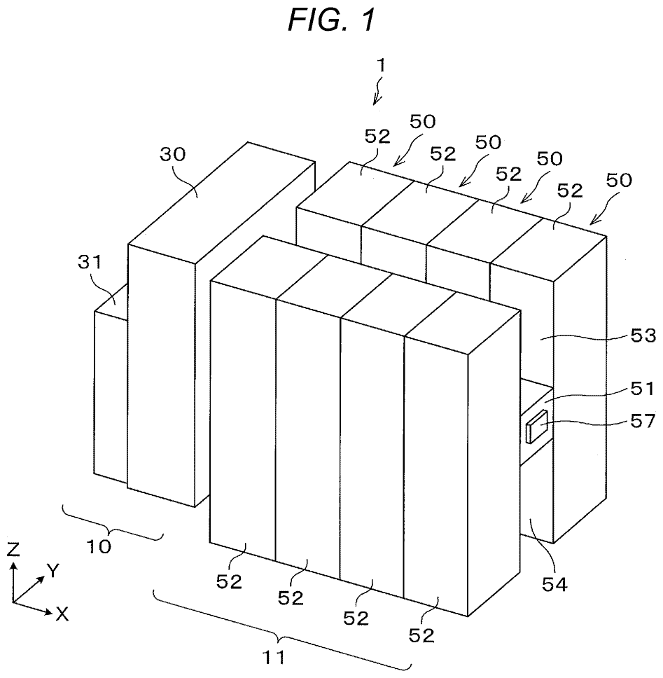

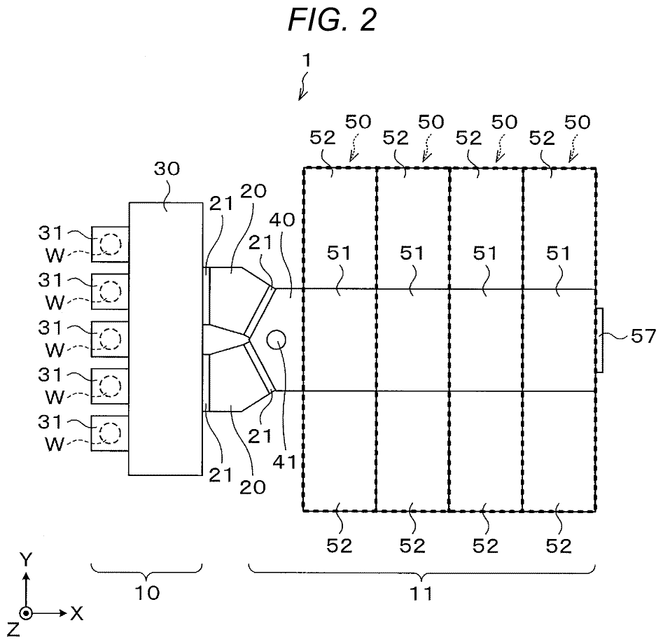

First, a wafer processing apparatus according to the present embodiment will be described. FIG. 1 is a perspective view illustrating a schematic configuration of a wafer processing apparatus 1. FIG. 2 is a plan view illustrating the schematic configuration of the wafer processing apparatus 1. In the wafer processing apparatus 1, a wafer W that is a substrate is subjected to plasma processing such as etching processing, film formation processing, and diffusion processing.

As illustrated in FIGS. 1 and 2, the wafer processing apparatus 1 has a configuration in which an atmospheric unit 10 and a vacuum unit (a decompression unit) 11 are integrally connected to each other via two load-lock modules 20. The atmospheric unit 10 includes an atmospheric module that performs desired processing on the wafer W under an atmospheric atmosphere. The vacuum unit 11 includes a vacuum module (a decompression module) that performs desired processing on the wafer W under a vacuum atmosphere (a vacuum environment).

The load-lock module 20 is provided to connect a loader module 30 to be described later of the atmospheric unit 10 and a connection module 40 and a composite module 50 to be described later of the vacuum unit 11 via gate valves 21 and 21. The load-lock module 20 is configured to temporarily hold the wafer W. The load-lock module 20 is configured such that an inside thereof is switched between the atmospheric pressure atmosphere and the vacuum atmosphere.

The atmospheric unit 10 includes the loader module 30 including a transfer unit (not illustrated) for the wafer W, and load ports 31 on each of which a hoop (not illustrated) is placed. The hoops can store the wafers W. An orienter module (not shown) that adjusts an orientation of the wafer W in a horizontal direction, a buffer module (not shown) that temporarily stores the plurality of wafers W, and the like may be connected to the loader module 30.

The loader module 30 has a rectangular housing, and an inner space of the housing is maintained in an atmospheric pressure atmosphere. The load ports 31, for example, five load ports 31, are arranged side by side on one side surface forming a long side of a housing of the loader module 30 in a Y-axis direction. The two load-lock modules 20 are arranged side by side on the other side surface forming a long side of the housing of the loader module 30.

The vacuum unit 11 includes the connection module 40 and a plurality of, for example, four composite modules 50. The connection module 40 and the four composite modules 50 are connected to one another side by side in an X-axis direction from a side of the load-lock module 20. In the following description, an X-axis negative direction side may be referred to as a front side, and an X-axis positive direction side may be referred to as a rear side.

The connection module 40 is connected to the two load-lock modules 20 and one forwardmost composite module 50. In the present embodiment, end surfaces of the two load-lock modules 20 on the X-axis positive direction side (end surfaces on a side of the forwardmost composite module 50) are inclined in different directions. Meanwhile, as to be described later, a front end surface (an end surface on a side of the load-lock module 20) 55a of the forwardmost composite module 50 in the transfer chamber 51 is a flat surface. Therefore, the two load-lock modules 20 and the forwardmost transfer chamber 51 cannot be directly connected, and the connection module 40 that connects the two load-lock modules 20 and the forwardmost transfer chamber 51 is provided. When the two load-lock modules 20 and the forwardmost transfer chamber 51 can be directly connected, the connection module 40 may be omitted.

An exhaust port 41 for vacuuming a communication transfer space of the four transfer chambers 51 to be described later is formed in a bottom surface of the connection module 40. The exhaust port 41 is connected to a vacuum pump (not illustrated) including, for example, a dry pump or a turbo molecular pump. When the connection module 40 is omitted as described above, the exhaust port 41 may be formed in a bottom surface of the forwardmost transfer chamber 51.

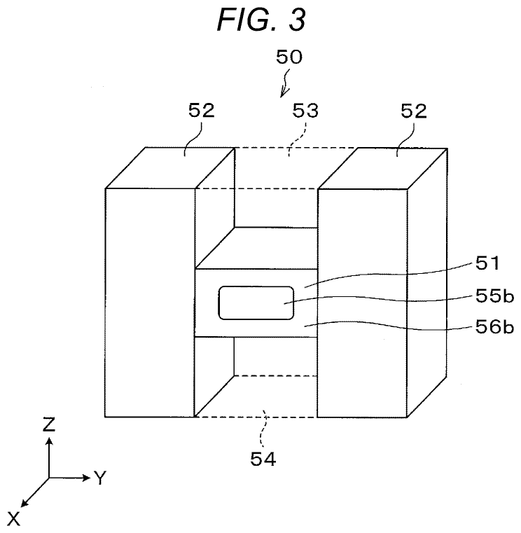

The four composite modules 50 have the same configuration. As illustrated in FIG. 3, the composite module 50 has a configuration in which one transfer chamber 51 and two processing chambers 52 are integrated. The two processing chambers 52 are provided on both sides in a direction (a Y-axis positive direction and a Y-axis negative direction) orthogonal to a connection direction of the transfer chamber 51 with respect to the connection direction (the X-axis direction) of the transfer chamber 51. Space areas are formed above and below the transfer chamber 51 between the two processing chambers 52. In the following description, the space area above the transfer chamber 51 will be referred to as an upper common area 53, and the space area below the transfer chamber 51 will be referred to as a lower common area 54.

A transfer space for transferring the wafer W is formed in the transfer chamber 51. The transfer chamber 51 is configured to maintain the transfer space in a vacuum atmosphere by vacuuming the transfer space from the exhaust port 41.

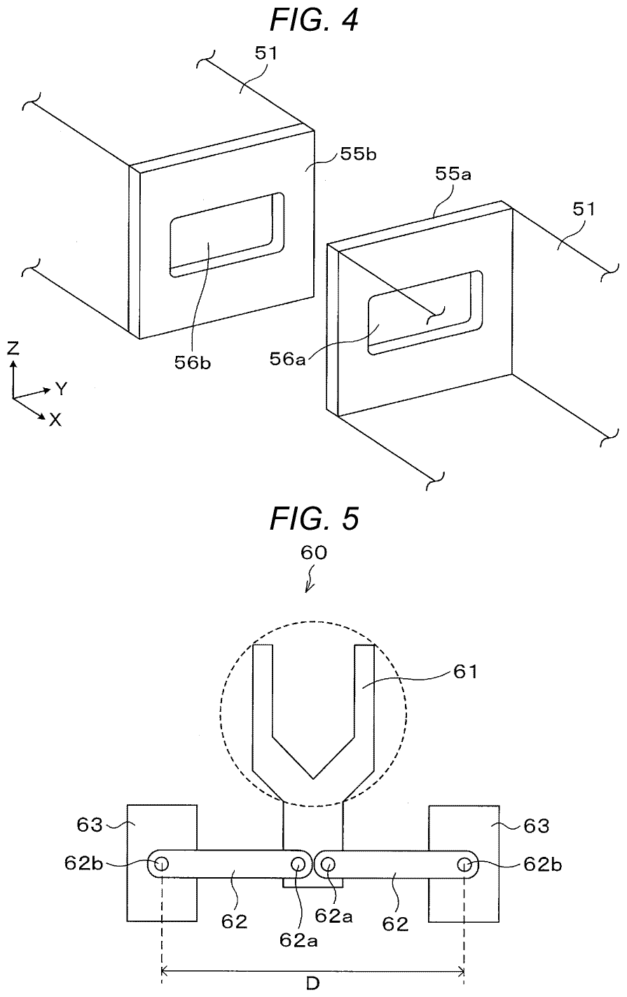

As illustrated in FIG. 4, the front end surface (the end surface in the X-axis negative direction) 55a in the connection direction of the transfer chamber 51 is a flat surface, and an opening 56a is formed in the front end surface 55a. A rear end surface (an end surface in an X-axis positive direction) 55b in the connection direction of the transfer chamber 51 is a flat surface, and an opening 56b is formed in the rear end surface 55b. The openings 56a and 56b have the same shape, and when the transfer chambers 51 adjacent to each other are directly connected, the openings 56a and 56b are continuous. When the four transfer chambers 51 are connected, the four transfer spaces communicate with each other via the openings 56a and 56b. In the following description, a space in which the four transfer spaces communicate with each other may be referred to as the communication transfer space.

A method of connecting the transfer chambers 51 adjacent to each other can be any method as long as the transfer chambers 51 can be directly connected to each other. For example, the rear end surface 55b of the transfer chamber 51 on a front side and the front end surface 55a of the transfer chamber 51 on a rear side may be fixed by screws. At this time, a periphery of the opening 56a of the front end surface 55a and the opening 56b of the rear end surface 55b are sealed.

As illustrated in FIGS. 1 and 2, the forwardmost transfer chamber 51 among the four transfer chambers 51 is connected to the connection module 40. At this time, the front end surface 55a of the transfer chamber 51 and the connection module 40 are connected, and the opening 56a of the front end surface 55a and an opening (not illustrated) of the connection module 40 are continuous. A periphery of these openings is sealed.

The opening 56b of the rear end surface 55b of the rearmost transfer chamber 51 among the four transfer chambers 51 is closed by, for example, a plate 57.

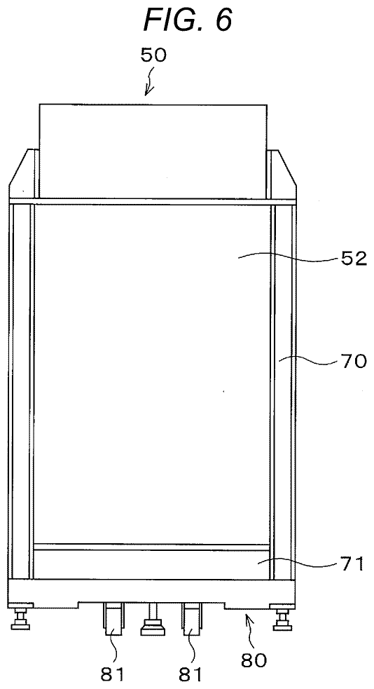

As described above, the four transfer chambers 51 are connected, and a magnetic levitation transfer unit 60 is provided in the communication transfer space in which the four transfer spaces communicate with each other. As illustrated in FIG. 5, the transfer unit 60 includes an end effector 61, two links 62, and two bases 63. The end effector 61 holds the wafer W. Each of the links 62 connects the end effector 61 and the base 63. One end portion of the link 62 is connected to the end effector 61 to be rotatable around a rotation axis 62a in a vertical direction. The other end portion of the link 62 is connected to the base 63 to be rotatable around a rotation axis 62b in the vertical direction. The two links 62 can be extended and retracted while maintaining an orientation of the end effector 61 by changing an interval D between the two rotation axes 62b (the two bases 63). The base 63 is provided with permanent magnets.

A planar motor (not illustrated) is provided on a bottom surface of the communication transfer space. Coils (not illustrated) are provided in the planar motor, and a magnetic field is generated by supplying a current to the coils. The base 63 including the permanent magnets floats and moves by the magnetic field generated by the coils. That is, the transfer unit 60 is magnetically levitated above the planar motor and moves above the planar motor. At this time, by controlling a current value of the coils, a position, an orientation, and a floating amount of the base 63 can be controlled.

The number of transfer units 60 provided in the communication transfer space is not limited. One transfer unit 60 may be provided, or transfer units 60 may be provided.

A processing space for processing the wafer W is formed in the processing chamber 52. The processing chamber 52 is configured to maintain the processing space in the vacuum atmosphere. In the processing space, the wafer W is subjected to plasma processing such as the etching processing, the film formation processing, and the diffusion processing. The processing space communicates with the transfer space of the transfer chamber 51 via a wafer loading and unloading port (not illustrated). The wafer loading and unloading port is configured to be opened and closed by using a gate valve (not illustrated).

Apparatuses required for wafer processing are provided in the processing chamber 52. Among the apparatuses, apparatuses that can be shared by two processing chambers 52 are provided in a common area of at least one of the upper common area 53 and the lower common area 54. Examples of such apparatuses include an utility source, a gas box, a gas line, a vacuum pump, a vacuum line, and a cooling water supply mechanism. Whether these apparatuses are provided in one common area of the upper common area 53 and the lower common area 54 or in both of the common areas can be freely designed.

The utility source is, for example, a power source that supplies power to various apparatuses. The gas box supplies a gas required for the plasma processing into the processing space of the processing chamber 52. The gas line supplies a gas from the gas box to the processing chamber 52. The vacuum pump includes, for example, a dry pump or a turbo molecular pump, and vacuums the processing space of the processing chamber 52. The vacuum line is a line that connects the vacuum pump and the processing chamber 52. The cooling water supply mechanism supplies cooling water to an apparatus that requires cooling water.

Among the apparatuses provided in the processing chamber 52, apparatuses that are not shared by the two processing chambers 52 are provided separately at positions of the respective processing chambers 52.

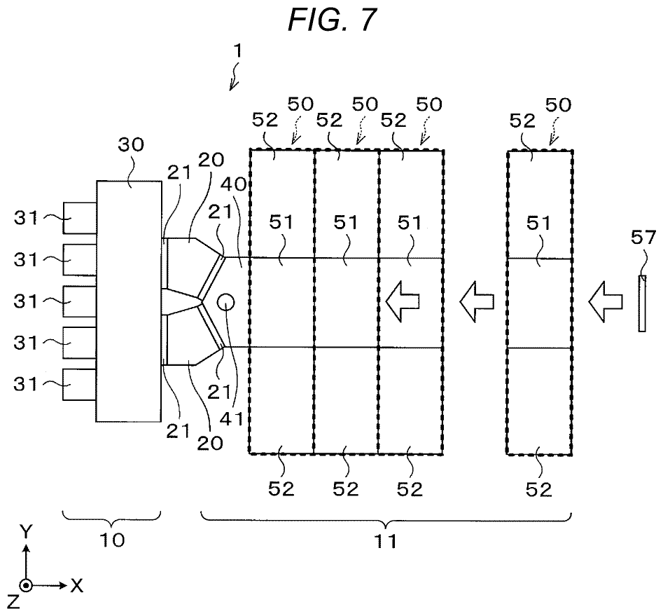

As described above, the composite module 50 has a configuration in which one transfer chamber 51 and two processing chambers 52 are integrated. As illustrated in FIG. 6, the transfer chamber 51 and the two processing chambers 52 are supported by a frame 70.

A detachable caster device 80 is attached to a leg portion 71 of the frame 70. The caster device 80 includes transfer casters 81, and moves the composite module 50 when producing the wafer processing apparatus 1 as to be described later. A configuration of the caster device 80 can be any configuration, and for example, a caster device disclosed in JP2022-109094A is used.

### <Method for Producing Wafer Processing Apparatus>

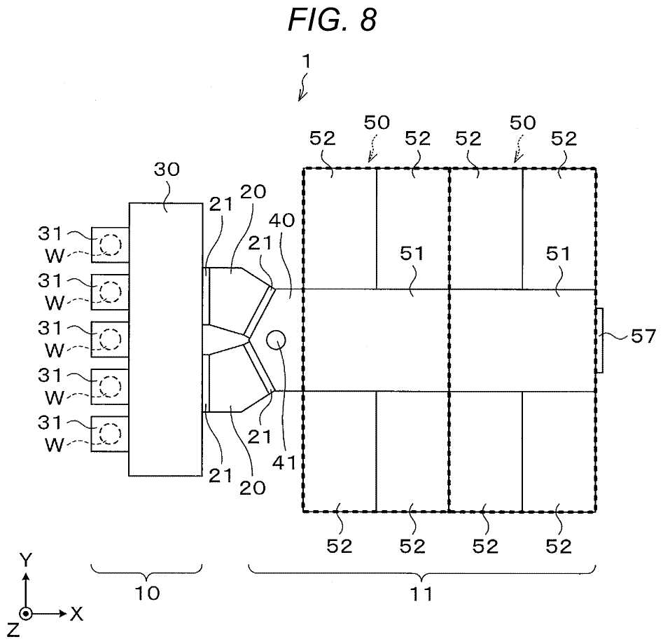

FIG. 7 is a view illustrating a method for producing the wafer processing apparatus 1. As illustrated in FIG. 7, when producing the wafer processing apparatus 1, first, the atmospheric unit 10, the two load-lock modules 20, and the connection module 40 are connected.

The caster device 80 is attached to each of the four composite modules 50. Subsequently, the four composite modules 50 are moved toward a side of the connection module 40, and the four composite modules 50 are connected to the connection module 40. Specifically, first, the transfer chamber 51 of the forwardmost composite module 50 is connected to the connection module 40. Subsequently, the transfer chamber 51 of the adjacent composite module 50 on the rear side is connected to the transfer chamber 51 of the composite module 50 on the front side, thereby linking the four composite modules 50.

Next, the transfer unit 60 is loaded into the communication transfer space of the four transfer chambers 51. Thereafter, the opening 56b formed in the rear end surface 55b of the transfer chamber 51 in the rearmost composite module 50 is closed by the plate 57.

When the wafer processing apparatus 1 is produced as described above, finally, the caster device 80 is removed from each of the four composite modules 50.

### Effects of Present Embodiment

According to the embodiment described above, since the composite module 50 has a configuration in which one transfer chamber 51 and two processing chambers 52 are integrated, the type (variation) of the transfer chamber 51 can be unified into one type. For example, in the examples in the related art illustrated in FIGS. 13A to 13E, four types of transfer modules 510a, 510b, 511a, and 511b are prepared according to the required number of processing modules 520. In contrast, in the present embodiment, the number of composite modules 50 can be increased or decreased according to the required number of processing chambers 52, and the transfer chamber 51 can be of one type.

Since the composite module 50 has a configuration in which one transfer chamber 51 and two processing chambers 52 are integrated, for example, wasteful spaces and layouts as illustrated in FIG. 15 of the related art can be eliminated. Therefore, it is possible to improve the production efficiency of the wafer processing apparatus 1.

Since the opening 56a formed in the front end surface 55a of the transfer chamber 51 and the opening 56b formed in the rear end surface 55b of the transfer chamber 51 have the same shape, one composite module 50 can be connected to any other composite module 50. Therefore, it is possible to further improve the production efficiency of the wafer processing apparatus 1.

It is required to perform an operation of separately connecting the processing modules 520 to the transfer modules 510 and 511 as illustrated in, for example, FIG. 14 in the related art, which requires labor. In contrast, in the present embodiment, since the composite module 50 in each of which one transfer chamber 51 and two processing chambers 52 are integrated may be connected to each other, labor may be reduced.

Among the apparatuses required for the wafer processing, an utility source, a gas box, a gas line, a vacuum pump, a vacuum line, and a cooling water supply mechanism can be provided in one common area of the upper common area 53 and the lower common area 54, or in both common areas, and can be shared by the two processing chambers 52. One transfer chamber 51 and two processing chambers 52 are supported by the frame 70, and the frame 70 can be shared by one transfer chamber 51 and two processing chambers 52. One caster device 80 is detachably provided for the composite module 50, and the caster device 80 can be shared by one transfer chamber 51 and two processing chambers 52. As described above, since the apparatuses individually provided for each processing chamber in the related art can be shared in the present embodiment, the wafer processing apparatus 1 can be simplified, and the apparatus cost can be reduced.

Further, since the transfer unit 60 provided in the communication transfer space of the four transfer chambers 51 is of a magnetic levitation type, the transfer unit 60 can be loaded after four composite modules 50 are connected to each other when producing the wafer processing apparatus 1. Accordingly, a degree of freedom in the configuration of the transfer chamber 51 is improved.

Further, when a fixed transfer unit is used as in the related art, it is required to perform maintenance of the transfer unit from above or below the transfer chamber. In contrast, when the magnetic levitation transfer unit 60 is used as in the present embodiment, since the transfer unit 60 can be extracted from the rearmost transfer chamber 51 and maintained, a space above or below the transfer chamber 51 can be used as the common areas 53 and 54.

Since the magnetic levitation transfer unit 60 can be provided regardless of the configuration of the transfer chamber 51, the configuration of the transfer chamber 51 can be made the same. As a result, an order in which the four composite modules 50 are coupled is not limited, and the degree of freedom in the production of the wafer processing apparatus 1 is improved.

In the related art, for example, when the first transfer module 510 and the second transfer module 511 are connected to each other as illustrated in FIGS. 13C to 13E, a pass module is required between the first transfer module 510 and the second transfer module 511. In contrast, when the magnetic levitation transfer unit 60 is used as in the present embodiment, such a pass module is not required.

### OTHER EMBODIMENTS

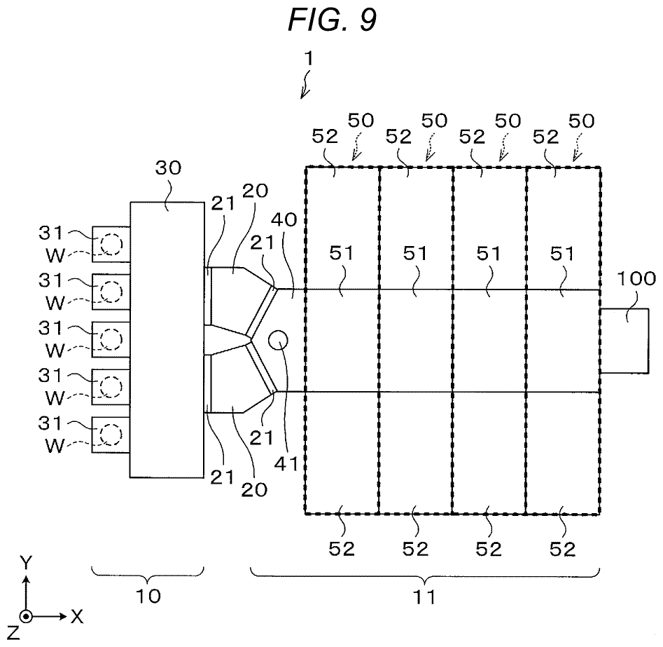

The wafer processing apparatus 1 according to the embodiment described above includes four processing chambers 52. However, the number of the processing chambers 52 is not limited thereto. The composite module 50 according to the embodiment described above has a configuration in which two processing chambers 52 are integrated with one transfer chamber 51. However, the composite module 50 may include one processing chamber 52 or three or more processing chambers 52. For example, as illustrated in FIG. 8, the composite module 50 may have a configuration in which one transfer chamber 51 and four processing chambers 52 are integrated.

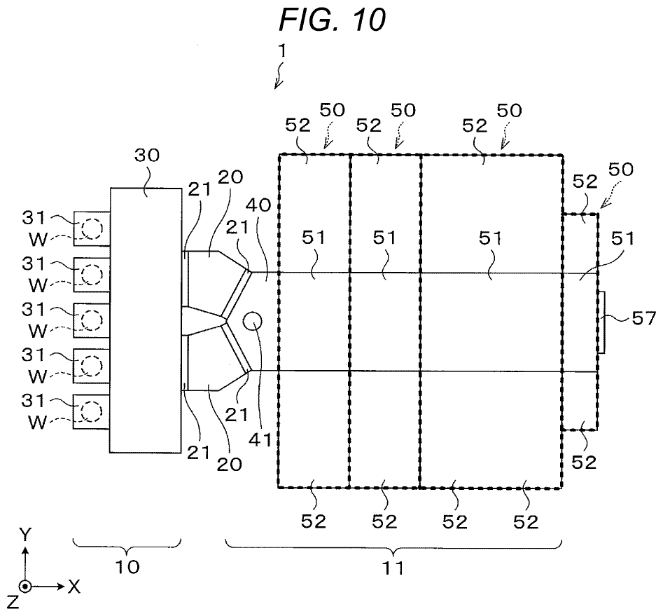

In the wafer processing apparatus 1 according to the embodiment described above, the opening 56b in the rear end surface 55b of the rearmost transfer chamber 51 is closed by the plate 57. However, as illustrated in FIG. 9, a pit-in chamber 100 may be connected to the rearmost transfer chamber 51. For example, a maintenance unit (not illustrated) is accommodated in the pit-in-chamber 100. The maintenance unit is a rescue unit that replaces the transfer unit 60 that is in failure. Alternatively, the maintenance unit is a cleaning unit that cleans the communication transfer space of the transfer chamber 51.

One pit-in chamber 100 is provided in the example of FIG. 9. However, the number of pit-in chambers 100 is not limited thereto. Another processing chamber, for example, a post-processing chamber for performing ashing processing on the wafer W after plasma processing may be connected to the rearmost transfer chamber 51.

In the embodiment described above, the wafer W is subjected to plasma processing in the processing chamber 52. However, another processing may be performed. For example, the post-processing such as ashing processing described above may be performed in the processing chamber 52. Alternatively, the pit-in chamber described above may be provided instead of the processing chamber 52.

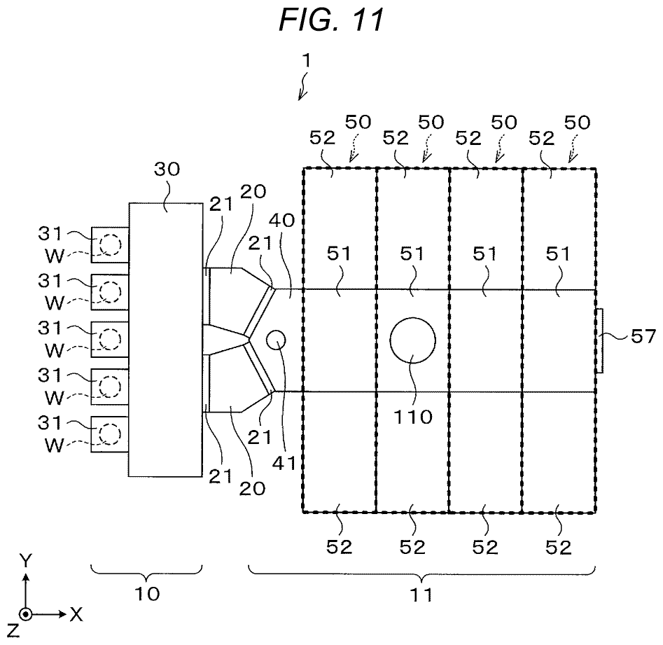

In the embodiment described above, lengths of the processing chambers 52 in the X-axis direction (the connection direction of the transfer chamber 51) are the same. However, the lengths may be different. When processing other than the plasma processing is performed in the processing chamber 52 as described above, and for example, five wafers W are batch-processed as illustrated in FIG. 10, the length of the processing chamber 52 in the X-axis direction becomes long. Further, the length of the composite module 50 in the X-axis direction also becomes long. Meanwhile, for example, when ashing processing or the like is performed, the size of the processing chamber 52 may be reduced, and the length of the processing chamber 52 in the X-axis direction is reduced. The length of the composite module 50 in the X-axis direction is also reduced. In any case, the widths of the transfer chambers 51 in the Y-axis direction are the same in the composite modules 50.

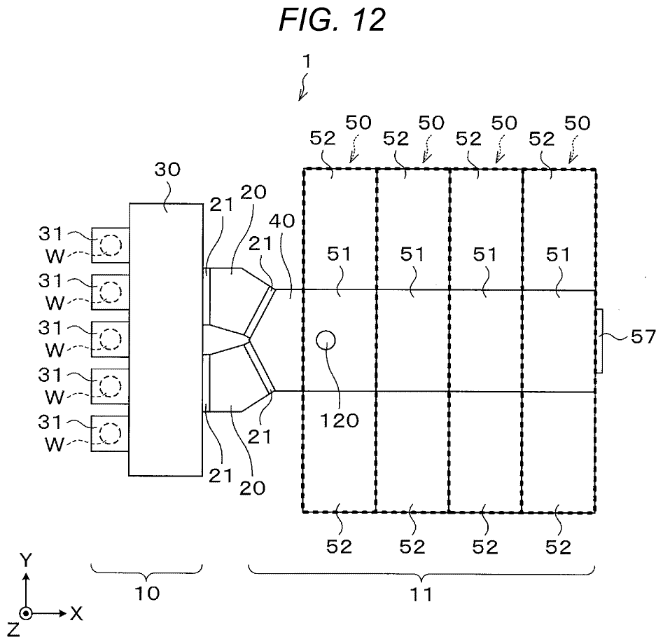

In the embodiment described above, the magnetic levitation transfer unit 60 is provided in the communication transfer space of the four transfer chambers 51. However, instead of the transfer unit 60, a fixed transfer unit 110 may be provided as illustrated in FIG. 11. The transfer unit 110 is fixed to one transfer chamber 51 among the four transfer chambers 51. The transfer unit 110 includes an arm (not illustrated) that can hold and transfer the wafer W, and the wafer W can be transferred between the two load-lock modules 20 and eight processing chambers 52 by the arm. The number of transfer units 110 in the communication transfer space can be freely selected and may be two or more.

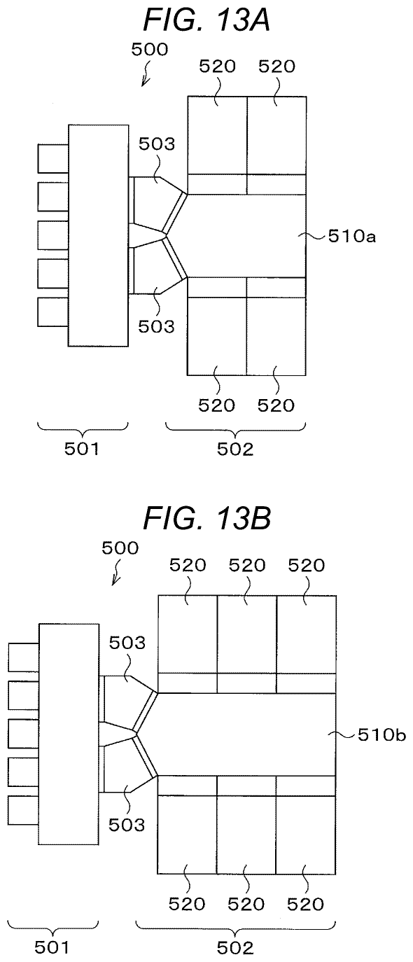

In the embodiment described above, the exhaust port 41 is provided in the bottom surface of the connection module 40. However, as illustrated in FIG. 12, an exhaust port 120 may be provided in the bottom surface of the forwardmost transfer chamber 51. The exhaust port 120 is connected to a vacuum pump (not illustrated) including, for example, a dry pump or a turbo molecular pump. However, when the exhaust port 41 is formed in the connection module 40 as in the embodiment described above, the configurations of the four transfer chambers 51 can be made common, and the production efficiency of the wafer processing apparatus 1 is improved.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The following configuration examples also fall within the technical scope of the present disclosure.
(1) A substrate processing apparatus for processing a substrate, the substrate processing apparatus having:
   composite modules in each of which one transfer chamber having a transfer space for the substrate and a processing chamber having a processing space for the substrate are integrated, in which
   the composite modules are connected by connecting the transfer chambers adjacent to each other.
(2) The substrate processing apparatus according to (1), in which
   the transfer chambers adjacent to each other are connected to each other directly.
(3) The substrate processing apparatus according to (1) or (2), in which
   the transfer spaces of the transfer chambers connected to each other communicate with each other.
(4) The substrate processing apparatus according to (3), in which
   a magnetic levitation transfer unit is provided in the transfer space.
(5) The substrate processing apparatus according to (3), in which
   at least one of the transfer chambers is provided with a transfer unit fixed to the transfer chamber.
(6) The substrate processing apparatus according to any one of (2) to (5), in which
   the transfer space is maintained in a vacuum atmosphere,
   the substrate processing apparatus further has:
      a load-lock module switchable between an atmospheric atmosphere and the vacuum atmosphere, and
      a connection module that connects the transfer chamber and the load-lock module, and
   an exhaust port configured to vacuum the transfer space is formed in the connection module.
(7) The substrate processing apparatus according to any one of (2) to (5), in which
   the transfer space is maintained in a vacuum atmosphere, and
   an exhaust port configured to vacuum the transfer space is formed in one of the transfer chambers.
(8) The substrate processing apparatus according to any one of (1) to (7), in which
   openings having a same shape are formed at both end surfaces of the transfer chamber.
(9) The substrate processing apparatus according to any one of (1) to (8), in which
   each of the composite modules has a configuration in which one chamber is partitioned into the one transfer chamber and two or more of the processing chambers.
(10) The substrate processing apparatus according to any one of (1) to (9), in which
   each of the composite modules has two or more of the processing chambers.
(11) The substrate processing apparatus according to (10), in which
   each of the composite modules has three or more of the processing chambers.
(12) The substrate processing apparatus according to any one of (1) to (11), in which
   each of the composite modules has a pit-in chamber in which a maintenance unit is accommodated.
(13) The substrate processing apparatus according to any one of (1) to (12), in which
   an apparatus required for processing the substrate is commonly provided in two or more of the processing chambers.
(14) The substrate processing apparatus according to (13), in which
   the apparatus is disposed in at least one of an upper common area formed above the transfer chamber and a lower common area formed below the transfer chambers in each of the composite modules.

1. A substrate processing apparatus for processing a substrate, the substrate processing apparatus comprising:
composite modules, each composite module including one transfer chamber having a transfer space for the substrate and a processing chamber integrated with the one transfer chamber and having a processing space for the substrate, wherein
the composite modules are connected by connecting the transfer chambers adjacent to each other.

2. The substrate processing apparatus according to claim 1, wherein
the transfer chambers adjacent to each other are directly connected.

3. The substrate processing apparatus according to claim 1, wherein
the transfer spaces of the transfer chambers connected to each other communicate with each other.

4. The substrate processing apparatus according to claim 3, wherein
a magnetic levitation transferer is provided in the transfer space.

5. The substrate processing apparatus according to claim 3, wherein
at least one of the transfer chambers is provided with a transferer fixed to the transfer chamber.

6. The substrate processing apparatus according to claim 3, wherein
the transfer space is maintained in a vacuum atmosphere,
the substrate processing apparatus further comprises:
a load-lock module switchable between an atmospheric atmosphere and the vacuum atmosphere; and
a connection module that connects the transfer chamber and the load-lock module, and
an exhaust port configured to vacuum the transfer space is formed in the connection module.

7. The substrate processing apparatus according to claim 3, wherein
the transfer space is maintained in a vacuum atmosphere, and
an exhaust port configured to vacuum the transfer space is formed in one of the transfer chambers.

8. The substrate processing apparatus according to claim 1, wherein
openings having a same shape are formed at both end surfaces of the transfer chamber.

9. The substrate processing apparatus according to claim 1, wherein
each of the composite modules has a configuration in which one chamber is partitioned into the one transfer chamber and the processing chamber.

10. The substrate processing apparatus according to claim 1, wherein
each of the composite modules has two or more of the processing chambers.

11. The substrate processing apparatus according to claim 10, wherein
each of the composite modules has three or more of the processing chambers.

12. The substrate processing apparatus according to claim 1, wherein
each of the composite modules has a pit-in chamber in which a cleaner is accommodated.

13. The substrate processing apparatus according to claim 1, wherein
an apparatus required for processing the substrate is commonly provided in two or more of the processing chambers.

14. The substrate processing apparatus according to claim 13, wherein
the apparatus is disposed in at least one of an upper common area formed above the transfer chamber and a lower common area formed below the transfer chambers in each of the composite modules.

15. A substrate processing apparatus for processing a substrate, the substrate processing apparatus comprising:
composite modules, each composite module including a transfer chamber, and each transfer chamber having a transfer space for the substrate; and
at least two processing chambers having processing spaces for the substrate,
wherein
the composite modules are connected by connecting the transfer chambers adjacent to each other, and an apparatus required for processing the substrate is shared by the at least two processing chambers and disposed in at least one of an upper common area formed above the transfer chamber or a lower common area formed below the transfer chamber in each composite module.

16. The substrate processing apparatus according to claim 15, wherein
each composite module is supported by a frame that supports the transfer chamber and the at least two processing chambers.

17. The substrate processing apparatus according to claim 15, wherein
a magnetic levitation transferer is provided in the transfer space to transfer the substrate between the composite modules.

18. A method for producing a substrate processing apparatus, comprising:
providing composite modules, each composite module including one transfer chamber having a transfer space for the substrate and at least one processing chamber having a processing space for the substrate;
connecting the composite modules by directly connecting the transfer chambers adjacent to each other to form a communication transfer space; and
installing a transferer in the communication transfer space to transfer the substrate between the composite modules.

19. The method according to claim 17, wherein
connecting the composite modules includes sealing openings formed at end surfaces of the transfer chambers to maintain the communication transfer space in a vacuum atmosphere.

20. The method according to claim 17, further comprising:
attaching a detachable caster device to each composite module to move the composite modules during connection, and removing the caster device after connecting the composite modules.
